(19) United States
(12) Patent Application Publication
(10) Pub. No.: US 2010/0128438 A1
(43) Pub. Date: May 27, 2010

(54) HEAT DISSIPATION MODULE

(75) Inventor: Ting-Chiang Huang, Taipei City (TW)

Correspondence Address: J C PATENTS, 4 VENTURE, SUITE 250, IRVINE, CA, 92618, US

(73) Assignee: INVENTEC CORPORATION, Taipei City (TW)

(21) Appl. No.: 12/622,035

(22) Filed: Nov. 19, 2009

(30) Foreign Application Priority Data
Nov. 27, 2008 (TW) 97146015

(51) Int. Cl. H05K 7/20; F28F 7/00

(52) U.S. Cl. 361/704; 165/185

(57) ABSTRACT

A heat dissipation module suitable for a heating element includes a heat dissipation unit and a cooling unit. The heat dissipation unit includes a body suitable for being contacted with the heating element and a heat dissipation fins set connected to the body. The cooling unit has a cooling surface and a heating surface, and is disposed on the heat dissipation fins set by the cooling surface.

### CROSS-REFERENCE TO RELATED APPLICATION

This application claims the priority benefit of Taiwan application serial no. 97146015, filed Nov. 27, 2008. The entirety of the above-mentioned patent application is hereby incorporated by reference herein and made a part of specification.

### BACKGROUND OF THE INVENTION

1. Field of the Invention

The present invention generally relates to a heat dissipation module, in particular, to a heat dissipation module capable of enhancing the heat convection by a cooling unit.

2. Description of Related Art

With rapid development of electronic science and technology, and in order to satisfy consumers' requirements, new electronic products are continuously coming forth in the market. So far as a computer is concerned, in order to make the computer system operate normally, electronic elements having high heat power in the computer system, such as Central Processing Unit (CPU), memory module, Graphics Processing Unit (GPU) and chipset, have to additionally provided with a heat dissipation module to bring extra heat energy out of the electronic elements, thus preventing the temperature of the electronic elements during operation from exceeding the normal upper service temperature.

Conventional heat dissipation module generally includes a heat sink used for contacting with a heating element. The heat sink includes a base and a plurality of fins connected to the base, in which the base is used for contacting with a surface of a electronic element requiring heat dissipation, receiving heat energy from the electronic element via a heat conducting manner, and conducting the heat energy to the fins on the base via the same manner. The fins are used for increasing heat dissipation area to improve the heat conducting efficiency of the heat sink.

Conventional heat dissipation module utilizes natural convection generated by a surface of the heat sink and forced air flow provided from the outside to improve the heat convection efficiency of the heat sink. That is, in addition to the heat sink, the heat dissipation module also includes a fan assembled at one side of the heat sink. The fan is used for providing forced air flow to improve the heat convection efficiency of the heat sink. However, as the fan of the conventional heat dissipation module may generate noise during operation, it is hard to compromise low noise and heat dissipation efficiency. In addition, for an environment in the presence of dust, the heat dissipation module with the fan is likely to absorb dust into the case of computer and then make the dust cover the heat sink, thus decreasing the heat dissipation efficiency.

### SUMMARY OF THE INVENTION

Accordingly, the present invention is directed to a heat dissipation module, for improving the heat dissipation performance by enhancing the convection efficiency.

The present invention provides a heat dissipation module suitable for a heating element. The heat dissipation module includes a first heat dissipation unit and a cooling unit. The heat dissipation unit includes a body suitable for being contacted with the heating element and a first heat dissipation fins set connected to the body. The cooling unit has a cooling surface and a heating surface, and is disposed on the first heat dissipation fins set by the cooling surface.

In an embodiment of the present invention, the above heat dissipation module further includes a second heat dissipation unit disposed on the cooling unit and contacted with the heating surface.

In an embodiment of the present invention, the second heat dissipation unit includes a second fins set.

In an embodiment of the present invention, the above heat dissipation module further includes a heat absorbing unit disposed between the cooling unit and the first heat dissipation fins set and contacted with the cooling surface.

In an embodiment of the present invention, the heat absorbing unit includes a third fins set.

In an embodiment of the present invention, an extension direction of the third fins set is substantially vertical to an extension direction of the first fins set.

In an embodiment of the present invention, in the above heat dissipation module, the cooling unit is a cooling chip.

In view of the above, the heat dissipation module of the present invention is capable of generating a low temperature region over the heat dissipation unit by the cooling unit to enhance the heat convection efficiency of the heat dissipation module. Moreover, the heat dissipation module of the present invention may substitute for the conventional fan heat dissipation module, so the electronic product can apply to more different environments, such as environments which must be noise-free or environments in the presence of dust.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an exploded view of a heat dissipation module according to an embodiment of the present invention.

FIG. 2 is an assembled view of the heat dissipation module of FIG. 1.

FIG. 3 is a cross-sectional view of the heat dissipation module of FIG. 2 taken along line I-I.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

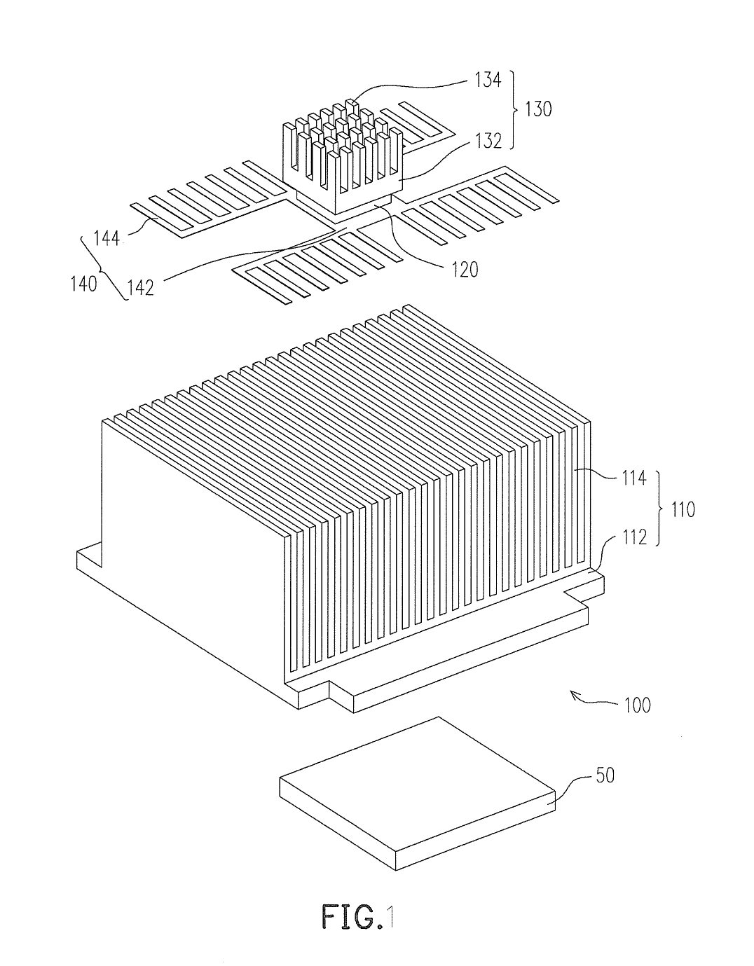

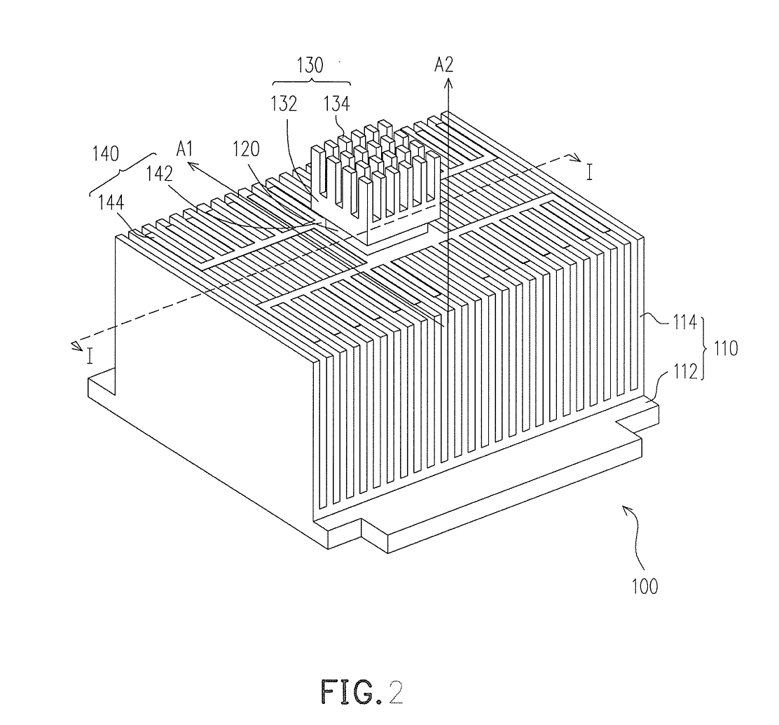

FIG. 1 and FIG. 2 are an exploded view and an assembled view of a heat dissipation module according to an embodiment of the present invention respectively. Referring to FIG. 1 and FIG. 2, the lower part of a heat dissipation module 100 is contacted with a heating element 50 to receive the heat energy from the heating element 50. The heat dissipation module 100 includes a first heat dissipation unit 110 and a cooling unit 120. The heat dissipation unit 110 includes a first body 112 and a first heat dissipation fins set 114. The first heat dissipation fins set 114 is connected to the body 112, and the first body 112 is suitable for being contacted with the heating element 50. In this embodiment, the heating element 50 is, for example, a Central Processing Unit (CPU) or a graphics chip.

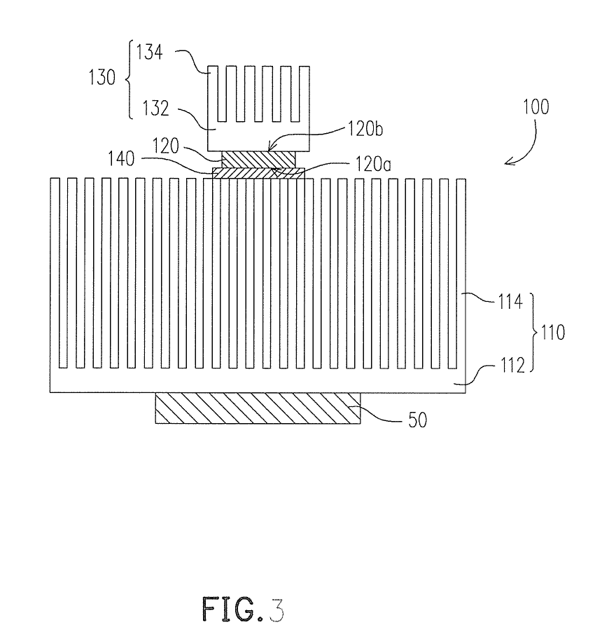

FIG. 3 is a cross-sectional view of the heat dissipation module of FIG. 2 taken along line I-I. Referring to FIG. 3, the cooling unit 120 is a cooling chip, and the cooling unit 120 has a cooling surface 120a and a heating surface 120b, so as to absorb the heat from the outside by the cooling surface 120a and dissipate the heat out by the heating surface 120b. The cooling unit 120 is disposed on the first heat dissipation fins set 114 by the cooling surface 120a to receive the heat energy of the heat dissipation fins set 114, thereby generating a low temperature region over the heat dissipation unit 110. The air in the low temperature region falls because its density becomes larger after cooling, and the air surrounding the heat dissipation unit 110 rises because of the heating of the heating element 50. In this way, the heat convection efficiency is enhanced by the density difference between the cold air and the hot air, thereby improving the heat dissipation performance.

In this embodiment, the heat dissipation module 100 may further include a second heat dissipation unit 130. The second heat dissipation unit 130 is disposed on the cooling unit 120 and is contacted with the heating surface 120b to absorb the heat energy from the heating surface 120b. The second heat dissipation unit 130 includes a second body 132 and a second fins set 134. The second fins set 134 is connected to the second body 132 to increase the heat dissipation area of the second heat dissipation unit 130, thereby improving the heat dissipation performance.

In addition, the heat dissipation module 100 may further include a heat absorbing unit 140. The heat absorbing unit 140 is disposed between the cooling unit 120 and the first heat dissipation fins set 114, and is contacted with the cooling surface 120a. The heat absorbing unit 140 is, for example, a heat sink, and includes a third body 142 and a third fins set 144. Referring to FIG. 2, the third fins set 144 extends on two sides, for example, and the first fins set 114 may extend at the gravity direction. That is, the extension direction A1 of the third fins set 144 is substantially vertical to the extension direction A2 of the first fins set 114. In this way, the cooling unit 120 cools the heat absorbing unit 140 below and generates a low temperature region at the extension area of the third fins set 144.

In view of the above, the heat dissipation module of this embodiment generates a low temperature region at the relatively high place of the heat dissipation module by a cooling element, and due to the density difference of the air, cold air in the low temperature region falls and hot air at the relatively lower place of the heat dissipation module rises. In this way, the heat convection efficiency is enhanced, thereby improving the heat dissipation performance. Moreover, the heat dissipation module of this embodiment may substitute for the conventional fan heat dissipation module, so the electronic product can apply to more different environments, such as environments which must be noise-free or environments in the presence of dust.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat dissipation module suitable for a heating element, comprising:
a first heat dissipation unit, comprising a body and a first heat dissipation fins set, wherein the first heat dissipation fins set is connected to the body and the body is suitable for being contact with the heating element; and
a cooling unit, having a cooling surface and a heating surface, wherein the cooling unit is disposed on the heat dissipation fins set by the cooling surface.

2. The heat dissipation module according to claim 1, further comprising:
a second heat dissipation unit, disposed on the cooling unit and contacted with the heating surface.

3. The heat dissipation module according to claim 2, wherein the second heat dissipation unit comprises a second fins set.

4. The heat dissipation module according to claim 1, further comprising a heat absorbing unit, disposed between the cooling unit and the heat dissipation fins set and contacted with the cooling surface.

5. The heat dissipation module according to claim 4, wherein the heat absorbing unit comprises a third fins set.

6. The heat dissipation module according to claim 5, wherein an extension direction of the third fins set is substantially vertical to an extension direction of the first fins set.

7. The heat dissipation module according to claim 1, wherein the cooling unit is a cooling chip.
